(19) United States
(12) Patent Application Publication
(10) Pub. No.: US 2026/0299219 A1
(43) Pub. Date: Oct. 1, 2026

(54) Semiconductor Device and Method of Forming Fan-Out Wafer Level CPO with Through Silicon Conductive Via

(71) Applicant: STATS ChipPAC Pte. Ltd., Singapore (SG)

(72) Inventors: Gai Leong Lai, Singapore (SG); Swain Hong Alfred Yeo, Singapore (SG)

(73) Assignee: STATS ChipPAC Pte. Ltd., Singapore (SG)

(21) Appl. No.: 19/090,055

(22) Filed: Mar. 25, 2025

(51) Int. Cl. G02B 6/42; G02B 6/12; H01L 21/48; H01L 21/56; H01L 21/683; H01L 21/768; H01L 23/00; H01L 23/367; H01L 23/373; H01L 23/522; H01L 23/528; H01L 23/538; H01L 25/16; H05K 1/18

(52) U.S. Cl. CPC G02B 6/4206; G02B 6/12004; G02B 6/4269; H10W 20/056; H10W 20/42; H10W 20/43; H10W 40/228; H10W 70/02; H10W 70/611; H10W 70/65; H10W 90/401; G02B 6/4245; G02B 6/428; H05K 1/181; H10P 72/74; H10W 40/258; H10W 72/0198; H10W 72/07232; H10W 72/07236; H10W 72/29; H10W 72/877; H10W 74/01; H10W 90/00; H10W 90/724; H10W 90/736

(57) ABSTRACT

A semiconductor device has a first electrical component with a coupler formed on a first surface of the first electrical component. The first electrical component can be a PIC and the coupler is an optically sensitive region. An encapsulant is deposited over and around the first electrical component. A conductive via is formed through the first electrical component. A clear coating is disposed over the coupler. A first interconnect structure is formed within a cavity of the encapsulant over the first surface of the first electrical component outside the coupler. A second interconnect structure is formed over a second surface of the first electrical component. An optical interposer panel is disposed over the first interconnect structure and encapsulant with an optical block disposed over the coupler. A second electrical component is disposed over the optical interposer panel. A heat spreader is disposed over the second electrical component.

### FIELD OF THE INVENTION

The present invention relates in general to semiconductor devices and, more particularly, to a semiconductor device and method of forming a fan-out wafer level CPO with through silicon conductive vias.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Some semiconductor die utilize a coupler to convert one signal to another signal. For example, a photonic integrated circuit (PIC) uses an optical sensitive area to convert optical data to electrical signals. The PIC must optically communicate with an external optical source and electrically communicate with other semiconductor devices. It would be preferrable to construct the PIC package at the wafer level to simplify the manufacturing procedure and save manufacturing cost. However, PIC integration at the wafer level has been complex, particularly with defects arising from a lack of protection for the optically sensitive area of the semiconductor die.

### BRIEF DESCRIPTION OF THE DRAWINGS

FIGS. 1a-1f illustrate a semiconductor wafer with a plurality of semiconductor die separated by a saw street;

FIGS. 2a-2r illustrate a process of forming a fan-out wafer level CPO with through mold conductive vias;

FIG. 3 illustrates the CPO with through mold conductive vias; and

FIG. 4 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

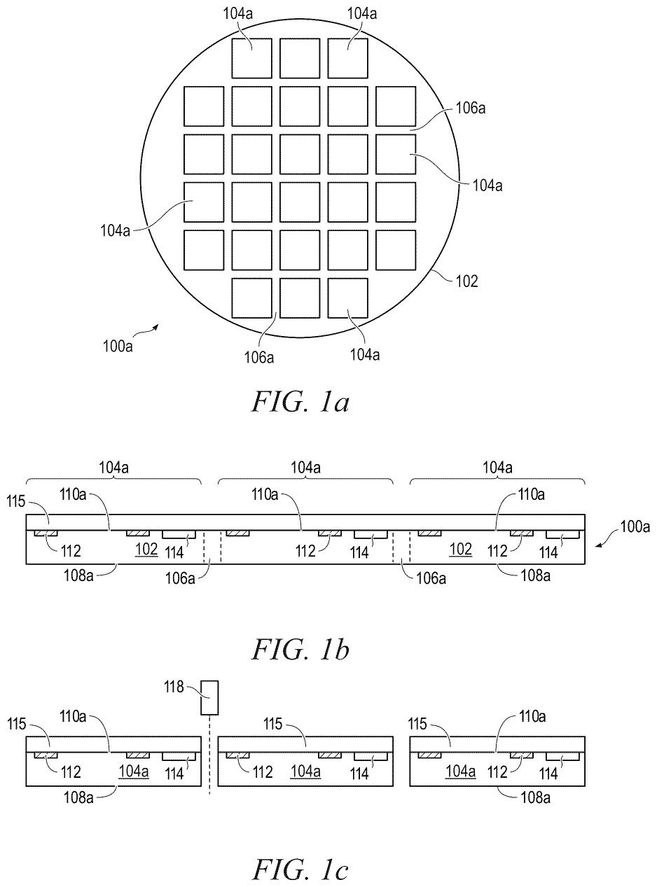

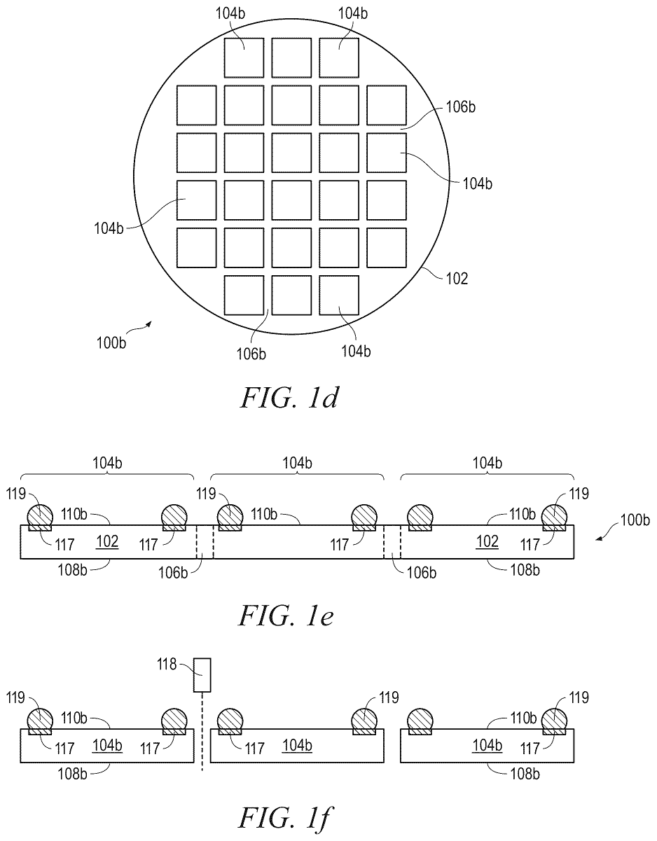

FIG. 1a shows a semiconductor wafer 100a with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104a is formed on wafer 100a separated by a non-active, inter-die wafer area or saw street 106a. Saw street 106a provides cutting areas to singulate semiconductor wafer 100a into individual semiconductor die 104a. In one embodiment, semiconductor wafer 100a is circular with a diameter of 100-450 millimeters (mm). Semiconductor wafer 100a can be rectangular or any other geometric shape.

FIG. 1b shows a cross-sectional view of a portion of semiconductor wafer 100a. Each semiconductor die 104a has a back or non-active surface 108a and an active layer 110a containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active layer 110 to implement analog circuits or digital circuits, such as digital signal processor (DSP), application specific integrated circuits (ASIC), memory, or other signal processing circuit. Semiconductor die 104a may also contain IPDs, such as inductors, capacitors, and resistors, for RF signal processing.

An electrically conductive layer 112 is formed over or within active layer 110a using PVD, CVD, electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads or redistribution layer (RDL) electrically connected to the circuits in active layer 110a. Portions of conductive layer 112 can be electrically common or electrically isolated depending on the design and function of semiconductor die 104a within semiconductor wafer 100a and other electrical components.

Each semiconductor die 104a further contains coupler 114. Coupler 114 can have a variety of applications to couple or convert one signal to another signal. In one embodiment, coupler 114 receives light and converts the light to an electrical signal. In that case, coupler 114 is a light sensitive region or optical device, and semiconductor die 104a would be considered a PIC. A conformal protection layer 115 is formed over active surface 110a and coupler 114. Protection layer 115 can be a sacrificial mask, photoresist, or epoxy.

In FIG. 1c, semiconductor wafer 100a is singulated through saw street 106a using a saw blade or laser cutting tool 118 into individual semiconductor die 104a. The individual semiconductor die 104a can be inspected and electrically tested for identification of known good die or unit (KGD/KGU) post singulation.

In another case, FIG. 1d shows a semiconductor wafer 100b, made similar to semiconductor wafer 100a. A plurality of semiconductor die or components 104b is formed on wafer 100b separated by a non-active, inter-die wafer area or saw street 106b. Saw street 106b provides cutting areas to singulate semiconductor wafer 100b into individual semiconductor die 104b. In one embodiment, semiconductor wafer 100b is circular with a diameter of 100-450 mm. Semiconductor wafer 100b can be rectangular or any other geometric shape.

FIG. 1e shows a cross-sectional view of a portion of semiconductor wafer 100b. Each semiconductor die 104b has a back or non-active surface 108b and an active layer 110b containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active layer 110 to implement analog circuits or digital circuits, such as DSP, ASIC, memory, or other signal processing circuit. Semiconductor die 104b may also contain IPDs, such as inductors, capacitors, and resistors, for RF signal processing. Semiconductor die 104b may have a different electrical function as semiconductor die 104a.

An electrically conductive layer 117 is formed over or within active layer 110b using PVD, CVD, electrolytic plating, electroless plating process, or other suitable metal deposition process. Conductive layer 117 can be one or more layers of Al, Cu, Sn, Ni, Au, Ag, or other suitable electrically conductive material. Conductive layer 117 operates as contact pads or RDL electrically connected to the circuits in active layer 110b.

An electrically conductive bump material is deposited over conductive layer 120 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 117 using a suitable attachment or bonding process. In one embodiment, the bump material is reflowed by heating the material above its melting point to form balls or bumps 119. In one embodiment, bump 119 is formed over an under bump metallization (UBM) having a wetting layer, barrier layer, and adhesive layer. Bump 119 can also be compression bonded or thermocompression bonded to conductive layer 117. Bump 119 represents one type of interconnect structure that can be formed over conductive layer 117. The interconnect structure can also use bond wires, conductive paste, stud bump, micro bump, or other electrical interconnect.

In FIG. 1f, semiconductor wafer 100b is singulated through saw street 106b using a saw blade or laser cutting tool 118 into individual semiconductor die 104b. The individual semiconductor die 104b can be inspected and electrically tested for identification of KGD/KGU post singulation.

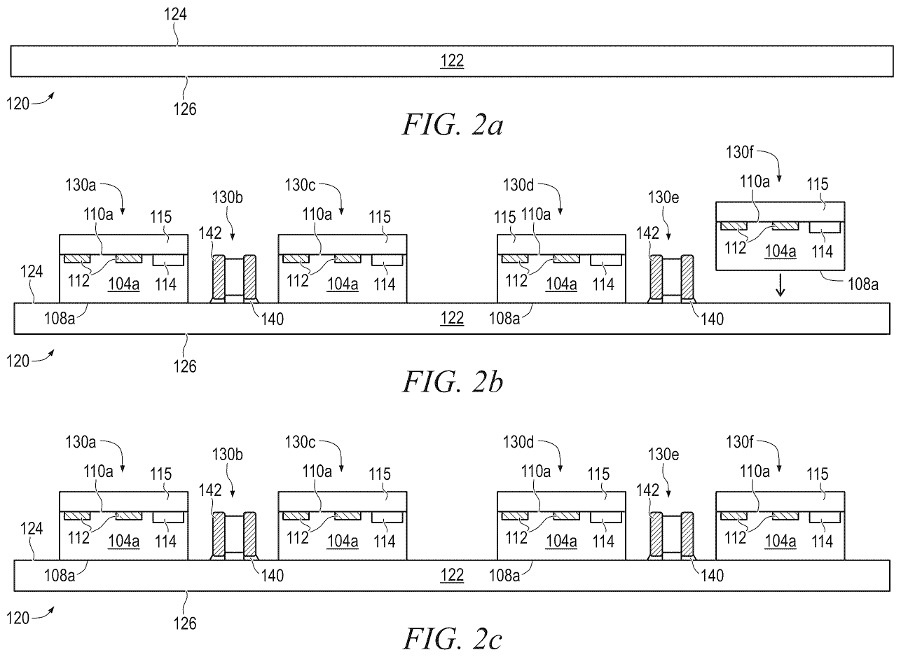

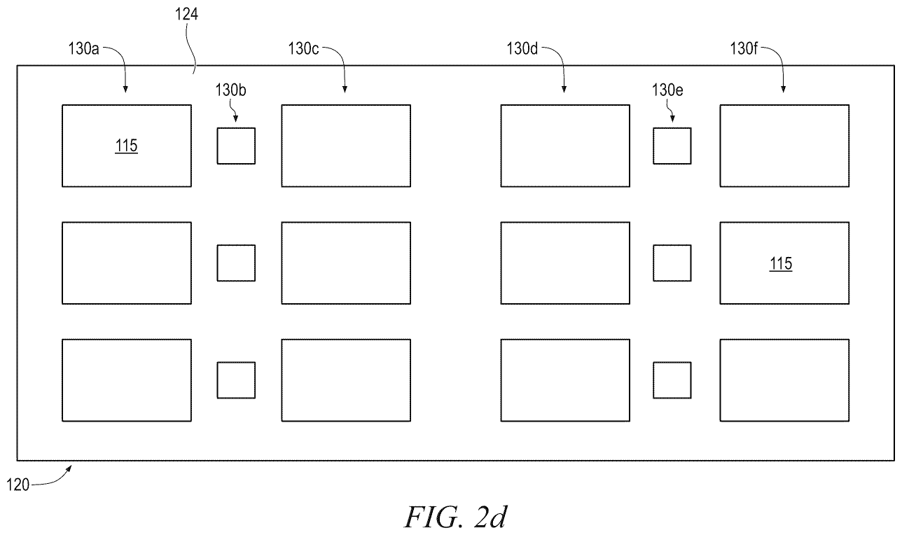

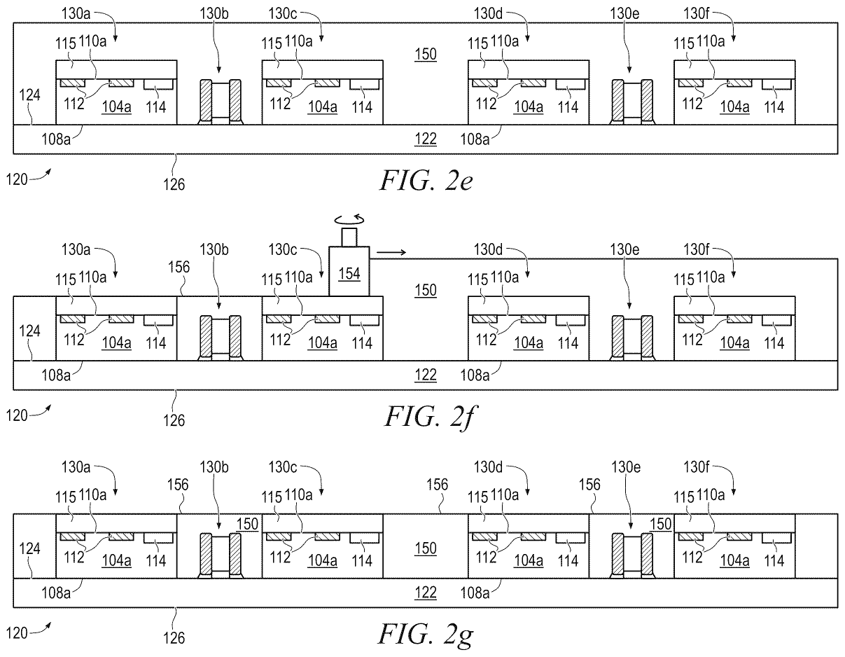

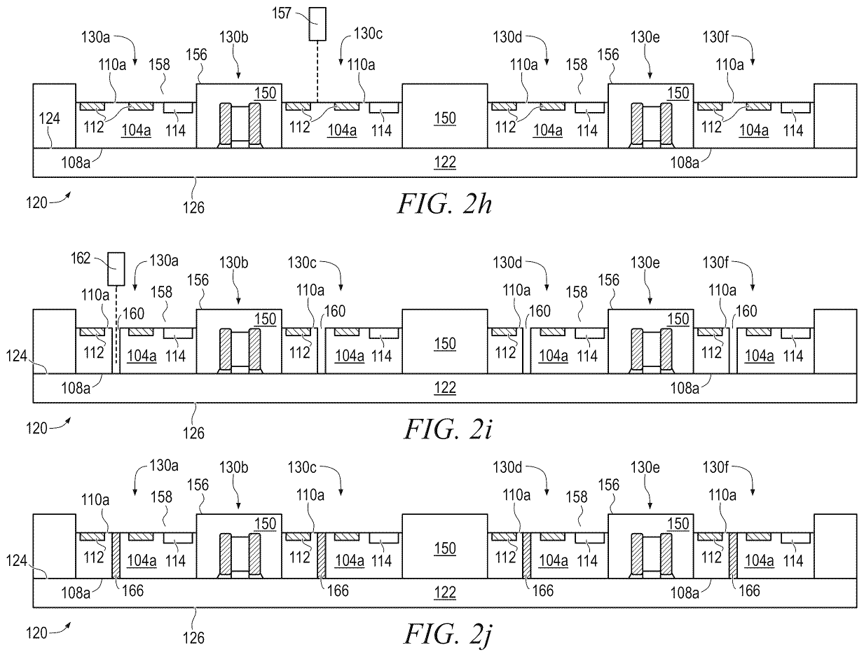

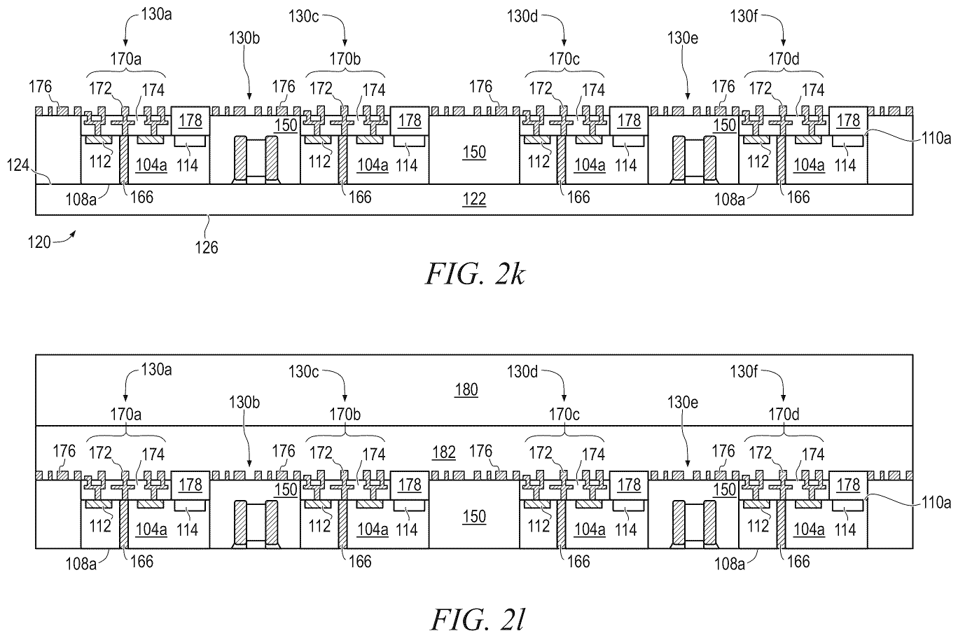

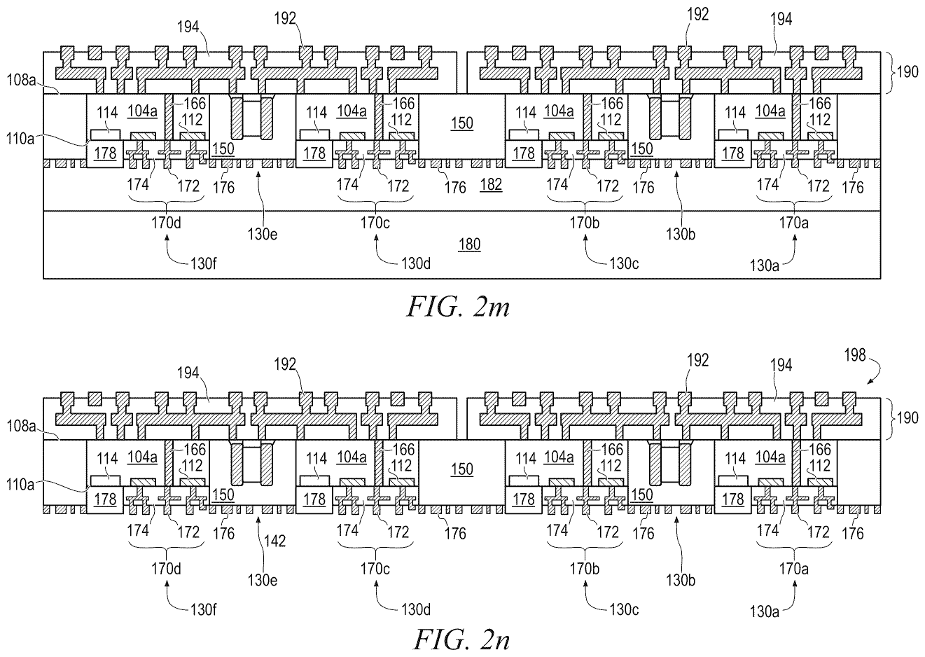

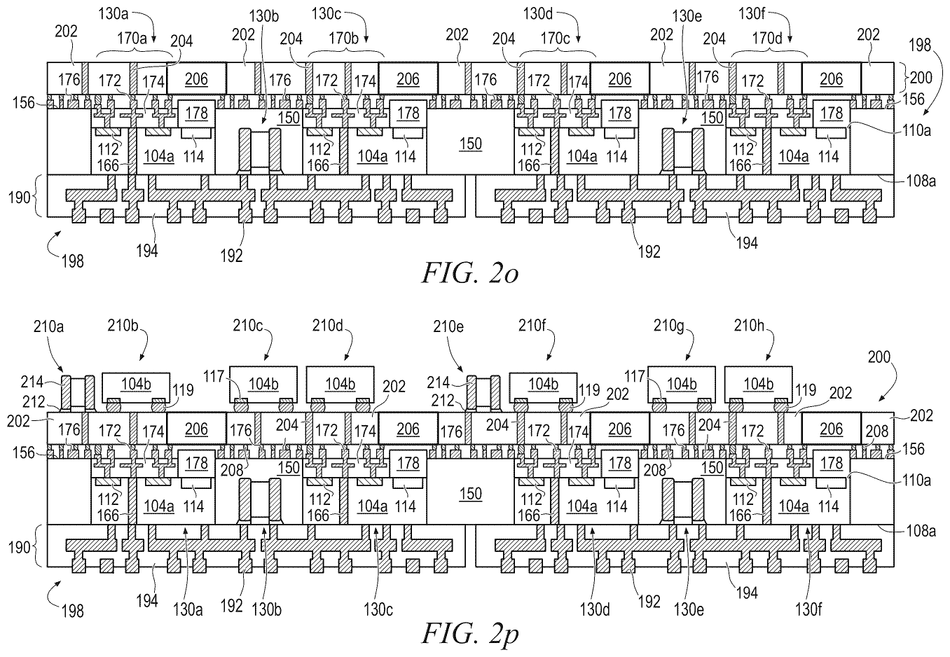

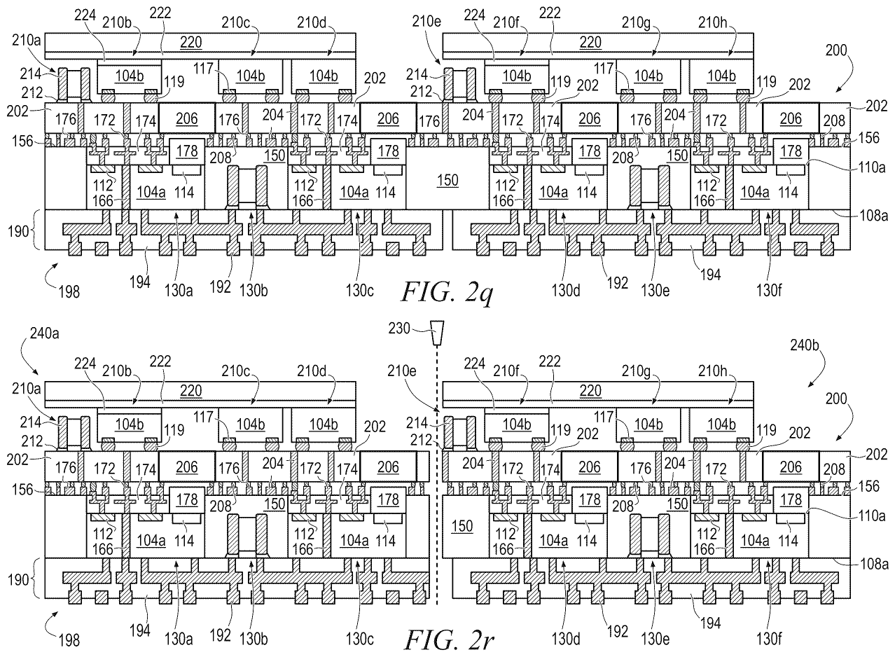

FIGS. 2a-2r illustrate a process of forming a fan-out wafer level co-packaged optics (CPO) with through silicon conductive vias. FIG. 2a shows a cross-sectional view of substrate 120 including core material 122, such as silicon, germanium, aluminum phosphide, aluminum arsenide, gallium arsenide, gallium nitride, indium phosphide, silicon carbide, or other bulk material for structural support. Alternatively, core material 122 can be a multi-layer flexible laminate, ceramic, CCL, or epoxy molding compound. Core material 122 may contain one or more layers of Al, Cu, Sn, Ni, Au, Ag, or other suitable electrically conductive material. Core material 122 may contain one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Preferably, core material 122 is glass or metal. Substrate 120 has a major surface 124 and major surface 126 opposite surface 124.

In FIG. 2b, electrical components 130a-130f are positioned over surface 124 of substrate 120 using a pick and place operation. For example, electrical components 130b and 130e can be discrete electrical devices, such as a resistor, capacitor, inductor, transistor, or diode. Electrical components 130b and 130e have terminals 142 bonded to conductive vias 204 with solder or conductive paste 140. Electrical components 130a, 130c, 130d, and 130f can be similar to semiconductor die 104a from FIG. 1c, as a PIC with coupler 114 oriented away from surface 124. Alternatively, electrical components 130a, 130c, 130d, and 130f can include other semiconductor die, semiconductor packages, surface mount devices, discrete electrical devices, or IPDs. FIG. 2c shows electrical components 130a-130f disposed over surface 124 of substrate 120 with coupler 114 facing up with protective layer 115 providing protection for the coupler. FIG. 2d is a top view of electrical components 130a-130f disposed over surface 124 of substrate 120.

In FIG. 2e, an encapsulant or molding compound 150 is deposited over and around electrical components 130a-130f using a paste printing, compressive molding, transfer molding, liquid encapsulant molding, vacuum lamination, spin coating, or other suitable applicator. Encapsulant 150 can be polymer composite material, such as epoxy resin with filler, epoxy acrylate with filler, or polymer with proper filler. Encapsulant 150 is non-conductive, provides structural support, and environmentally protects the semiconductor device from external elements and contaminants.

In FIG. 2f, a portion of encapsulant 150 is removed by grinder 154 to planarize surface 156 of the encapsulant and expose protective layer 115. FIG. 2g shows planarized surface 156 of encapsulant 150 and the exposed protective layer 115.

In FIG. 2h, protective layer 115 is removed by laser 157 to expose coupler 114 and form mold cavity 158. Alternatively, protective layer 115 can be removed by chemical etching, chemical mechanical polishing (CMP), mechanical peel-off, mechanical grinding, thermal bake, ultra-violet (UV) light, or wet stripping to expose coupler 114 and form mold cavity 158. Active surface 110a in mold cavity 158 is subjected to plasma cleaning.

In FIG. 2i, a portion of core material 102 in electrical components 130b-130d is removed by an etching process or laser 162 to form openings 160 extending from surface 156 through the core material to surface 124. In FIG. 2j, an electrically conductive material is formed within openings 160 using PVD, CVD, electrolytic plating, electroless plating process, or other suitable metal deposition process to form through silicon conductive vias 166. Conductive vias 166 can be one or more layers of Al, Cu, Sn, Ni, Au, Ag, or other suitable electrically conductive material.

In FIG. 2k, interconnect structures 170a-170d are formed over active surface 110a of electrical components 130a, 130c, 130d, and 130f outside a region or footprint of coupler 114. Each interconnect structure 170a-170d includes one or more conductive layers 172 and one or more insulating layers 174. Conductive layers 172 can be one or more layers of Al, Cu, Sn, Ni, Au, Ag, or other suitable electrically conductive material. Conductive layers 172 can be formed using PVD, CVD, electrolytic plating, electroless plating process, or other suitable metal deposition process. Conductive layers 172 provide horizontal electrical interconnect (such as RDL), and vertical electrical interconnect. Portions of conductive layers 172 can be electrically common or electrically isolated depending on the design and function of electrical components 130a-130f and other electrical components. Insulating layers 174 contain one or more layers of SiO2, Si3N4, SiON, Ta2O5, Al2O3, solder resist, polyimide, BCB, PBO, and other material having similar insulating and structural properties. Insulating layers 174 can be formed using PVD, CVD, printing, lamination, spin coating, spray coating, sintering or thermal oxidation. Insulating layers 174 provide isolation between conductive layers 172. There can be multiple conductive layers like 172 separated by insulating layers 174.

An electrically conductive layer 176 is formed over encapsulant 150 and interconnect structures 170a-170d using PVD, CVD, electrolytic plating, electroless plating process, or other suitable metal deposition process. Conductive layer 176 can be one or more layers of Al, Cu, Sn, Ni, Au, Ag, or other suitable electrically conductive material. Conductive layer 176 makes electrical connection to conductive vias 166 and interconnect structures 170a-170d. A clear coating 178 is deposited over coupler 114. Clear coating 178 can be an adhesive or epoxy and provides protection for coupler 114.

In FIG. 2l, temporary substrate or carrier 180 is disposed over encapsulant 150, interconnect structures 170a-170d, conductive layer 176, and clear coating 178 with interface material 182. Carrier 180 can be a sacrificial base material, such as silicon, polymer, beryllium oxide, glass, or other suitable low-cost, rigid material for stiffening and structural support. Interface material 182 can be a polymer, epoxy, acryl-based B-stage material, photoresist, or other similar material.

In FIG. 2m, interconnect structures 190 are formed over back surface 108a of electrical components 130a, 130c, 130d, and 130f and encapsulant 150. Interconnect structure 190 includes one or more conductive layers 192 and one or more insulating layers 194. Conductive layers 192 can be one or more layers of Al, Cu, Sn, Ni, Au, Ag, or other suitable electrically conductive material. Conductive layers 192 can be formed using PVD, CVD, electrolytic plating, electroless plating process, or other suitable metal deposition process. Conductive layers 192 provide horizontal electrical interconnect (such as RDL), and vertical electrical interconnect. Portions of conductive layers 192 can be electrically common or electrically isolated depending on the design and function of electrical components 130a-130f and other electrical components. Insulating layers 194 contain one or more layers of SiO2, Si3N4, SiON, Ta2O5, Al2O3, solder resist, polyimide, BCB, PBO, and other material having similar insulating and structural properties. Insulating layers 194 can be formed using PVD, CVD, printing, lamination, spin coating, spray coating, sintering or thermal oxidation. Insulating layers 194 provide isolation between conductive layers 192. There can be multiple conductive layers like 192 separated by insulating layers 194.

In FIG. 2n, carrier 180 and interface material 182 are removed chemical etching, CMP, mechanical peel-off, mechanical grinding, thermal bake, UV light, or wet stripping to expose interconnect structures 170a-170d, conductive layer 176, and clear coating 178. The assembly shown in FIG. 2n constitutes a wafer level PIC package 198.

In FIG. 2o, wafer level PIC package 198 is inverted and optical interposer panel 200 is disposed over interconnect structures 170a-170d, conductive layer 176, and clear coating 178. Optical interposer panel 200 has insulative material 202, conductive vias 204, and optical block 206. In one embodiment, insulative material 202 is glass. Optical interposer panel 200 can be pre-formed with conductive vias 204 and employed using chip-on-wafer-on-substrate (CoWoS) stacking integration of multiple interfacing electrical components 130a-130f. Optical interposer panel 200 uses optical blocks 206 for dimensional fiber coupling without vertical or horizontal coupling. Conductive vias 204 make electrical connection to interconnect structures 170a-170d and conductive layer 176 through bumps 208. Optical block 206 is disposed over clear coating 178 and coupler 114 and operates as a waveguide.

In FIG. 2p, electrical components 210a-210h are positioned over optical interposer panel 200 using a pick and place operation, similar to FIG. 2b. For example, electrical components 210a and 210e can be discrete electrical devices, such as a resistor, capacitor, inductor, transistor, or diode. Electrical components 210a and 210e have terminals 214 bonded to conductive vias 204 with solder or conductive paste 212. Electrical components 210b-210d and 210f-210h can be similar to semiconductor die 104b from FIG. 1f with bumps 119 oriented toward optical interposer panel 200. Alternatively, electrical components 210b-210d and 210f-210h can include other semiconductor die, semiconductor packages, surface mount devices, discrete electrical devices, or IPDs.

In FIG. 2q, heat spreader or heat sink 220 is bonded to electrical components 210b-210d and 210f-210h with thermal interface material 222. Heat spreader 220 is a block of solid material, such as steel, aluminum, copper, alloys thereof, or another thermally conductive material. Spacer 224 provides additional height if needed, depending on the height of the electrical components 210b-210d and 210f-210h. The assembly in FIG. 2q is a fan-out wafer level co-packaged optics package electrically interconnected, in part, with through mold conductive vias. In FIG. 2r, the assembly is singulated using a saw blade or laser cutting tool 230 into individual CPO packages 240a and 240b.

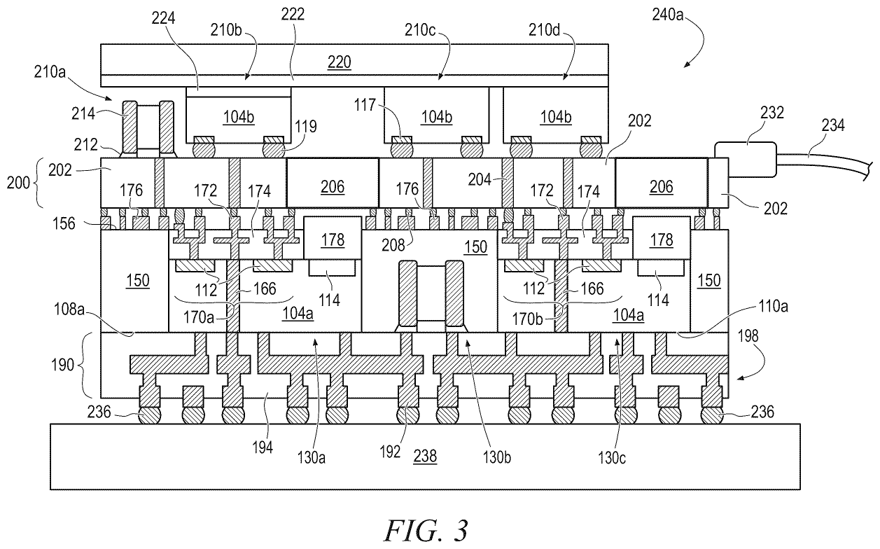

FIG. 3 shows CPO package 240a with interconnect structure 190, electrical components 130a-130b, encapsulant 150, conductive vias 166, interconnect structures 170a-170b, optical interposer panel 200, electrical components 210a-210d, and heat spreader 220. Optical connector 232 receives data from optical cable 234 and passes the light based information through optical interposer panel 200 and optical blocks 206 and clear coating 178 to coupler 114. CPO package 240 is coupled to substrate 238 via bumps 236. Substrate 238 can be a PCB with one or more conductive layers and one or more insulating layers, similar to interconnect structure 190. Coupler 114 converts the optical data into electrical signals. Electrical components 130a-130b process the electrical signals and communicate through interconnect structures 170a-170b, conductive layer 176, and conductive vias 204 to electrical components 210a-210d. Electrical components 130a-130b further communicate through conductive vias 166, interconnect structure 190, and bumps 236 to substrate 238. CPO package 240 contains multiple electrical components 130a-130b, implementing PICs, and communicating through optical interposer panel 200 and through mold conductive vias 166. In CPO package 240, coupler 114 is protected facing up. Interconnect structures 170a-170d are formed in mold cavity 158. Heat spreader 220 is stacked over electrical components 210a-210d for heat dissipation of CPO package 240.

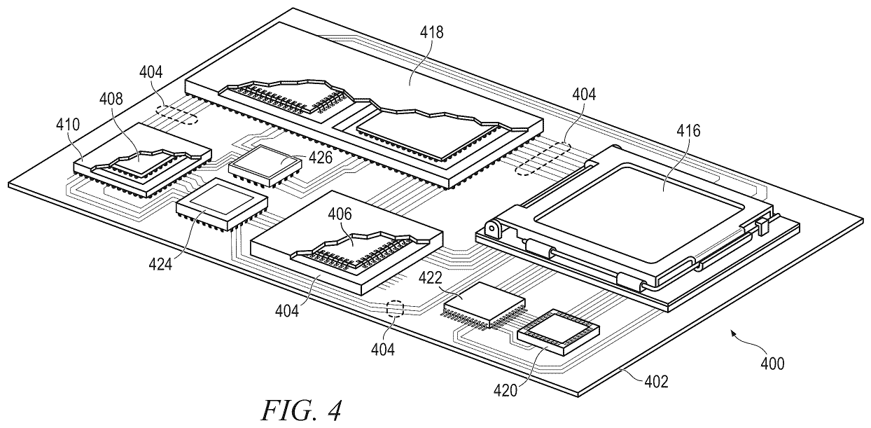

FIG. 4 illustrates electrical device 400 having a chip carrier substrate or PCB 402 with a plurality of semiconductor packages disposed on a surface of PCB 402, including CPO package 240a. Electrical device 400 can have one type of semiconductor package, or multiple types of semiconductor packages, depending on the application.

Electrical device 400 can be a stand-alone system that uses the semiconductor packages to perform one or more electrical functions. Alternatively, electrical device 400 can be a subcomponent of a larger system. For example, electrical device 400 can be part of a tablet, cellular phone, digital camera, communication system, or other electrical device. Alternatively, electrical device 400 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 4, PCB 402 provides a general substrate for structural support and electrical interconnect of the semiconductor packages disposed on the PCB. Conductive signal traces 404 are formed over a surface or within layers of PCB 402 using evaporation, electrolytic plating, electroless plating, screen printing, or other suitable metal deposition process. Signal traces 404 provide for electrical communication between each of the semiconductor packages, mounted components, and other external system components. Traces 404 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may have the first level packaging where the die is mechanically and electrically disposed directly on the PCB.

For the purpose of illustration, several types of first level packaging, including bond wire package 406 and flipchip 408, are shown on PCB 402. Additionally, several types of second level packaging, including ball grid array (BGA) 410, bump chip carrier (BCC) 412, land grid array (LGA) 416, multi-chip module (MCM) or SIP module 418, quad flat non-leaded package (QFN) 420, quad flat package 422, embedded wafer level ball grid array (eWLB) 424, and wafer level chip scale package (WLCSP) 426 are shown disposed on PCB 402. In one embodiment, eWLB 424 is a fan-out wafer level package (Fo-WLP) and WLCSP 426 is a fan-in wafer level package (Fi-WLP). Depending upon the system requirements, any combination of semiconductor packages, configured with any combination of first and second level packaging styles, as well as other electrical components, can be connected to PCB 402. In some embodiments, electrical device 400 includes a single attached semiconductor package, while other embodiments call for multiple interconnected packages. By combining one or more semiconductor packages over a single substrate, manufacturers can incorporate pre-made components into electrical devices and systems. Because the semiconductor packages include sophisticated functionality, electrical devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a first electrical component including a coupler formed on a first surface of the first electrical component;
an encapsulant deposited over and around the first electrical component;
a conductive via formed through the first electrical component;
a first interconnect structure formed within a cavity of the encapsulant over the first surface of the first electrical component outside the coupler; and
a second interconnect structure formed over a second surface of the first electrical component opposite the first surface of the first electrical component.

2. The semiconductor device of claim 1, further including a clear coating disposed over the coupler.

3. The semiconductor device of claim 1, further including an optical interposer panel disposed over the first interconnect structure and encapsulant with an optical block disposed over the coupler.

4. The semiconductor device of claim 3, further including a second electrical component disposed over the optical interposer panel.

5. The semiconductor device of claim 4, further including a heat spreader disposed over the second electrical component.

6. The semiconductor device of claim 1, wherein the semiconductor device is formed at the wafer level.

7. A semiconductor device, comprising:
a first electrical component including a coupler formed on a first surface of the first electrical component;
an encapsulant deposited around the first electrical component;
a conductive via formed through the first electrical component;
a first interconnect structure formed over the first surface of the first electrical component outside the coupler; and
a second interconnect structure formed over a second surface of the first electrical component opposite the first surface of the first electrical component.

8. The semiconductor device of claim 7, wherein the coupler includes an optically sensitive region.

9. The semiconductor device of claim 7, further including a clear coating disposed over the coupler.

10. The semiconductor device of claim 7, further including an optical interposer panel disposed over the first interconnect structure and encapsulant with an optical block disposed over the coupler.

11. The semiconductor device of claim 10, further including a second electrical component disposed over the optical interposer panel.

12. The semiconductor device of claim 11, further including a heat spreader disposed over the second electrical component.

13. The semiconductor device of claim 7, wherein the semiconductor device is formed at the wafer level.

14. A method of making a semiconductor device, comprising:
providing a first electrical component including a coupler formed on a first surface of the first electrical component;
depositing an encapsulant over and around the first electrical component;
forming a conductive via through the first electrical component;
forming a cavity in the encapsulant over the first surface of the first electrical component;
forming a first interconnect structure formed within the cavity of the encapsulant over the first surface of the first electrical component outside the coupler; and
forming a second interconnect structure over a second surface of the first electrical component opposite the first surface of the first electrical component.

15. The method of claim 14, further including disposing a clear coating over the coupler.

16. The method of claim 14, further including disposing an optical interposer panel over the first interconnect structure and encapsulant with an optical block disposed over the coupler.

17. The method of claim 16, further including disposing a second electrical component over the optical interposer panel.

18. The method of claim 17, further including disposing a heat spreader over the second electrical component.

19. The method of claim 14, further including forming the semiconductor device at the wafer level.

20. A method of making a semiconductor device, comprising:
providing a first electrical component including a coupler formed on a first surface of the first electrical component;
depositing an encapsulant around the first electrical component;
forming a conductive via through the first electrical component;
forming a first interconnect structure over the first surface of the first electrical component outside the coupler; and
forming a second interconnect structure over a second surface of the first electrical component opposite the first surface of the first electrical component.

21. The method of claim 20, wherein the coupler includes an optically sensitive region.

22. The method of claim 20, further including disposing a clear coating over the coupler.

23. The method of claim 20, further including disposing an optical interposer panel over the first interconnect structure and encapsulant with an optical block disposed over the coupler.

24. The method of claim 23, further including a second electrical component disposed over the optical interposer panel.

25. The method of claim 24, further including disposing a heat spreader disposed over the second electrical component.
